(19) United States
(12) Patent Application Publication
(10) Pub. No.: US 2025/0157548 A1
(43) Pub. Date: May 15, 2025

(54) MEMORY DEVICE AND OPERATION METHOD THEREOF

(71) Applicant: MACRONIX INTERNATIONAL CO., LTD., Hsinchu (TW)

(72) Inventors: Huai-Mu WANG, New Taipei City (TW); Han-Wen HU, Zhubei City (TW); Yung-Chun LI, New Taipei City (TW); Chih-Chang HSIEH, Hsinchu City (TW); Shang-Ting LIN, Hsinchu City (TW)

(21) Appl. No.: 18/610,368

(22) Filed: Mar. 20, 2024

Related U.S. Application Data
(60) Provisional application No. 63/548,543, filed on Nov. 14, 2023.

(51) Int. Cl. G11C 16/26; G11C 16/04

(52) U.S. Cl. CPC G11C 16/26; G11C 16/0483

(57) ABSTRACT

The disclosure discloses a memory device and an operation method thereof. A target memory cell and at least one replicated memory cell belonging to the same memory string are selected. A target weight value written into the target memory cell is replicated to the at least one replicated memory cell, wherein the target memory cell and the at least one replicated memory cell store the target weight value. In response to a command of reading or computing on the target memory cell received by the memory device, reading or computing is performed on the target memory cell and the at least one replicated memory cell simultaneously.

This application claims the benefit of U.S. provisional application Ser. No. 63/548,543, filed Nov. 14 2023, the subject matter of which is incorporated herein by reference.

### TECHNICAL FIELD

The disclosure relates in general to a memory device and an operation method thereof.

### BACKGROUND

Memory devices play a crucial role in electronic devices. They are essential components in computer systems and electronic devices used for storing and retrieving data. The following highlights some importance of memory devices.

Data Storage: Memory devices are used to store the programs and data necessary for the operation of computer systems and electronic devices. Advances in technology have led to an increase in memory device capacity, enabling the processing of larger and more complex data.

Fast Access: Memory devices provide fast data access speeds, contributing to the improvement of system performance, which is crucial for the operation of computer systems and electronic devices.

Running Applications: Larger memory capacity allows for the simultaneous operation of multiple applications, enhancing multitasking efficiency.

System Stability: The stability and reliability of memory devices directly impact system stability. Issues with memory devices can lead to system crashes or data corruption.

In summary, memory devices are indispensable in computer systems and electronic devices, influencing performance, operating speed, and system stability. For modern computer systems and electronic devices, having memory devices with appropriate capacity and high efficiency is key to achieving smooth operation and handling complex tasks.

In-Memory Computing (IMC) refers to storing data in memory (for example, random access memory (RAM)) to achieve faster data access and real-time analysis. IMC enhances data processing speed and performance.

Here are some characteristics and advantages of In-Memory Computing:

Fast Access: Storing data in main memory allows the system to access and retrieve data more quickly, as the read/write speed of RAM is much faster than traditional hard drives.

Real-time Analysis: IMC enables real-time analysis and queries, as data can be immediately retrieved from memory.

High Performance: By reducing data access time, IMC improves the overall performance of computer systems and electronic devices, especially in scenarios involving large amounts of data or requiring real-time feedback.

Big Data Processing: In a big data environment, IMC can more effectively process massive datasets, speeding up the processes of data analysis and mining.

IMC has applications in various fields, including financial services, Internet of Things (IoT), and analytics. By leveraging the advantages of main memory, IMC enhances the efficiency of data processing and drives the development of data-intensive applications.

However, at present, In-Memory Computing faces some challenges. FIG. 1A shows the ideal current distribution of memory cells, while FIG. 1B depicts the actual current distribution of memory cells. FIG. 1C illustrates the known multi-level current distribution.

From FIG. 1A, it can be seen that in the ideal current distribution of memory cells, the currents IHVT for logic 1 and ILVT for logic 0 have a narrower distribution, aiding in the accurate reading of logic 1 and logic 0. “k” represents the current value.

In contrast, in the actual current distribution of memory cells shown in FIG. 1B, the currents IHVT for logic 1 and ILVT for logic 0 have a wider distribution, affecting the accuracy of reading logic 1 and logic 0.

Due to the wide current distribution of memory cells in FIG. 1B, in the multi-level current distribution shown in FIG. 1C, the current distributions of different levels may overlap (aliasing), affecting the accuracy of reading stored bits (such as 000 and 001 . . . ).

Furthermore, due to differences in memory cell variations in Analog Vector-Vector Multiplication (VVM) or Multiply Accumulate Operation (MAC), the recall rate may decrease.

Therefore, there is a need for a memory device and its operating method that can maintain multi-level capacity of the memory device, reduce the overall computing current of in-memory computing, and thereby reduce computational noise and power consumption.

### SUMMARY

According to one embodiment, a method of operating a memory device is provided. The method comprises: selecting a target memory cell and at least one replicated memory cell belonging to the same memory string; replicating a target weight value written into the target memory cell to the at least one replicated memory cell, wherein the target memory cell and the at least one replicated memory cell store the target weight value; and in response to a command of reading or computing on the target memory cell received by the memory device, performing reading or computing on the target memory cell and the at least one replicated memory cell simultaneously.

According to another embodiment, a memory device is provided. The memory device comprises: a memory array; and a memory controller coupled to the memory array. The memory controller is configured to: selecting a target memory cell and at least one replicated memory cell belonging to the same memory string; replicating a target weight value written into the target memory cell to the at least one replicated memory cell, wherein the target memory cell and the at least one replicated memory cell store the target weight value; and in response to a command of reading or computing on the target memory cell received by the memory device, performing reading or computing on the target memory cell and the at least one replicated memory cell simultaneously.

### BRIEF DESCRIPTION OF THE DRAWINGS

FIG. 1A shows the ideal current distribution of memory cells

FIG. 1B depicts the actual current distribution of memory cells.

FIG. 1C illustrates the known multi-level current distribution.

FIG. 2 illustrates the architecture of a memory device according to an embodiment of the present disclosure.

FIG. 3 depicts the architecture of a memory device according to another embodiment of the present disclosure.

FIG. 4A compares the current distribution diagrams of the prior art and the present embodiment.

FIG. 4B compares the standard deviation of currents between the prior art and the present embodiment.

FIG. 4C compares the standard deviation of currents between the prior art and the present embodiment.

FIG. 5 illustrates a functional block diagram of a memory device according to an embodiment of the present disclosure.

FIG. 6 shows an operation method flowchart of the memory device according to an embodiment of the present disclosure.

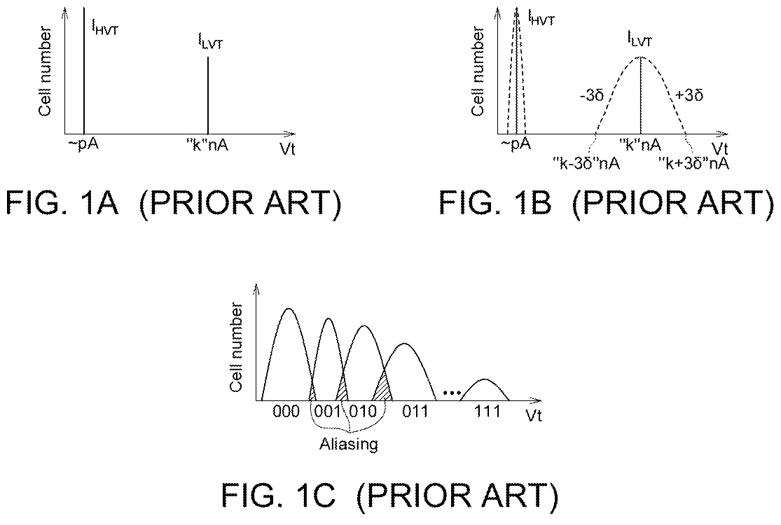

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

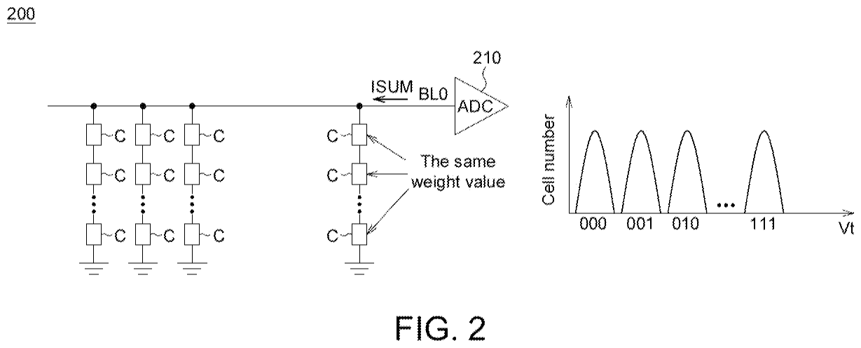

FIG. 2 illustrates the architecture of a memory device according to an embodiment of the present disclosure. As shown in FIG. 2, the memory device 200 according to one embodiment includes multiple memory cells C, at least one bit line BL0, and at least one analog-to-digital converter 210. FIG. 2 only shows a part of the memory device 200. In fact, the memory device 200 may include more elements. The memory cells C form multiple memory strings, where the memory cells C in each memory string are connected in series, and the memory strings are connected in parallel. The memory strings are coupled to the bit line BL0, and ISUM represents the total memory string current of the memory strings.

FIG. 2 also shows a current distribution diagram according to one embodiment. In this embodiment, during programming of a target memory cell, the stored data (or weight values) to be written into the target memory cell is replicated to at least one replicated memory cell belonging to the same memory string. As a result, the target memory cell and the at least one replicated memory cell have the same stored data (or weight values). When reading or performing in-memory computation on the target memory cell, the at least one replicated memory cell is also read or subjected to in-memory computation simultaneously. Therefore, for the same memory string, the equivalent resistance values of the target memory cell and the at least one replicated memory cell are added when they are simultaneously read or opened. As a result, the memory string current of the same memory string is reduced. The analog-to-digital converter 210 then performs analog-to-digital conversion on the total memory string current ISUM, converting into a digital output value that represents the result of in-memory computation.

In FIG. 2, by reducing the memory string current of the memory string, and thus the total current ISUM, the memory device 200 of the present embodiment has a narrow current distribution, preventing overlap of current distributions for different levels. This enhances data read accuracy and improves the accuracy of in-memory computation results.

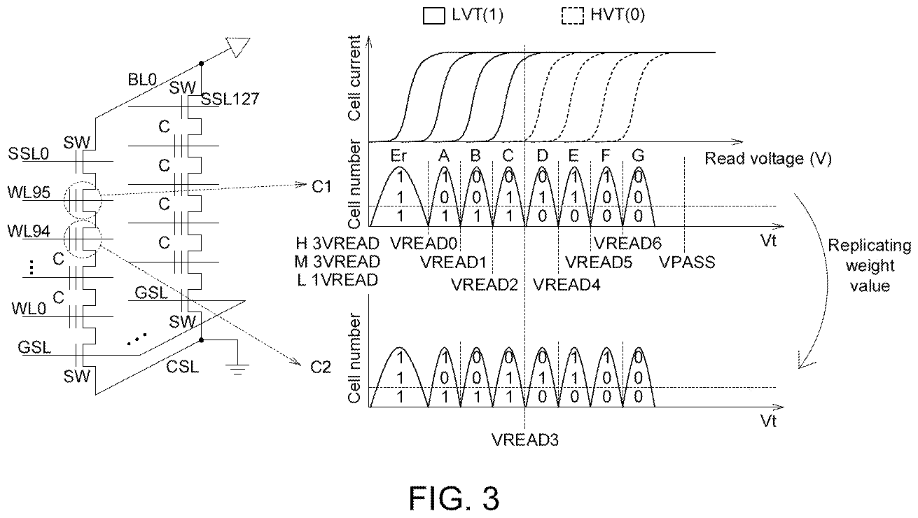

FIG. 3 depicts the architecture of a memory device according to another embodiment of the present disclosure. As shown in FIG. 3, the memory device 300 includes multiple memory cells C, multiple switches SW, at least one bit line, multiple word lines WL0-WL95, multiple string select lines SSL0-SSL127, a global select line GSL, and a common source line CSL. FIG. 3 only shows a part of the memory device 300. In fact, the memory device 300 may include more elements (for example, analog-to-digital converter). Similar to the previous embodiment, the memory cells C form multiple memory strings, and the memory strings are connected in parallel. The memory strings are coupled to the bit line BL0.

Similarly, in the memory device 300 of FIG. 3, during programming of a target memory cell C1, the stored data (or weight values) to be written into the target memory cell is replicated to at least one replicated memory cell C2 belonging to the same memory string. As a result, the target memory cell C1 and the at least one replicated memory cell C2 have the same stored data (or weight values). When reading or performing in-memory computation on the target memory cell C1, the at least one replicated memory cell C2 is also read or subjected to in-memory computation simultaneously. Therefore, when reading the target memory cell C1, the word lines WL95 (used to open the target memory cell C1) and WL94 (used to open the at least one replicated memory cell C2) are simultaneously selected to open the target memory cell C1 and the at least one replicated memory cell C2. Moreover, during in-memory computation, the word lines WL95 and WL94 receive the same input value. WL95 is referred to as the target word line, and WL94 is referred to as the replicated word line. As a result, for the same memory string, the equivalent resistance values of the target memory cell C1 and the at least one replicated memory cell C2 are added when the target memory cell C1 and the at least one replicated memory cell C2 are simultaneously read or opened. Thus, the memory string current of the same memory string is reduced. An analog-to-digital converter (not shown, similar to the analog-to-digital converter 210 in FIG. 2) then performs analog-to-digital conversion on the total memory string current, converting into a digital output value representing the result of in-memory computation.

FIG. 3 also shows a current distribution diagram according to this embodiment. By reducing the memory string current and thus the total current, the memory device 300 of the present embodiment has a narrow current distribution, preventing overlap of current distributions for different levels. This enhances data read accuracy and improves the accuracy of in-memory computation results. In FIG. 3, Er, A, B, C, D, E, F, and G represent states of the memory cells, where Er represents the erase state (programmed as logic 111), and A is programmed as logic 101, and so on.

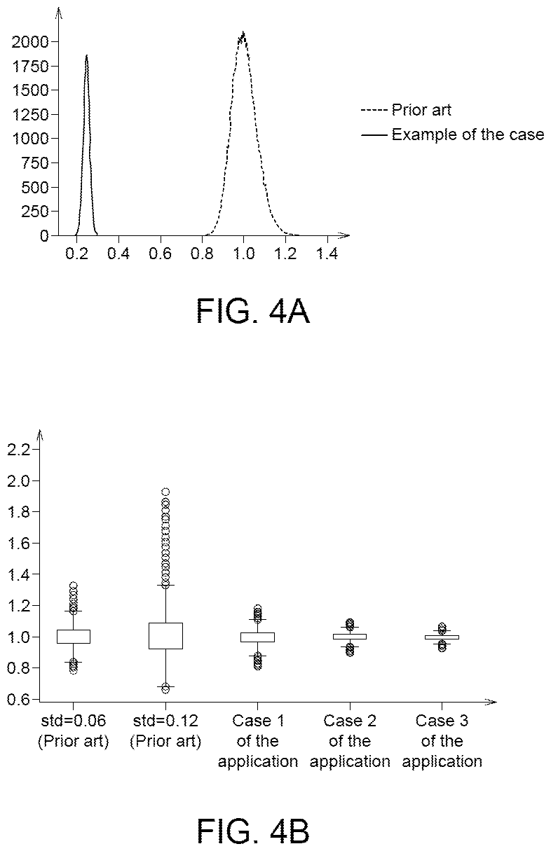

FIG. 4A compares the current distribution diagrams of the prior art and the present embodiment. In FIG. 4A, with a standard deviation of 0.12, the average current of the memory device in the present embodiment is approximately ¼ of the average current of the prior art memory device. Therefore, the present embodiment can effectively reduce the average current, avoiding misjudgments caused by current overlap during reading and effectively reducing power consumption.

FIG. 4B compares the standard deviation of currents between the prior art and the present embodiment. “Case 1 of the application” refers to having 1 target memory cell and 1 replicated memory cell in the same memory string (programmed with the same weight value), “Case 2 of the application” refers to having 1 target memory cell and 2 replicated memory cells in the same memory string (programmed with the same weight value), and “Case 3 of the application” refers to having 1 target memory cell and 3 replicated memory cells in the same memory string (programmed with the same weight value). From FIG. 4B, it can be seen that in the application, Case 1 to Case 3 have tighter current standard deviations, meaning that the present embodiment has a narrow current distribution, avoiding misjudgments caused by current overlap during reading and effectively reducing power consumption.

FIG. 4C compares the standard deviation of currents between the prior art and the present embodiment. From FIG. 4C, compared to the prior art (whether with a standard deviation of 0.06 or 0.12), Case 1 and Case 3 of the application have tighter current standard deviations, meaning that the present embodiment has a narrow current distribution, avoiding misjudgments caused by current overlap during reading and effectively reducing power consumption.

Table 1 compares the recall rates between the prior art and the present embodiment.

| | Input | | | | | |
|---|---|---|---|---|---|---|
| | bit | | | | | |
| | number | | Out- | | | |
| | and | | put | | | Recall |
| | weight | | bit | Memory | Return | rate at |
| | bit | Coarse | num- | variation | M | fine |
| | number | search | ber | (STD) | candidate | search |
| Prior art | 4 | 99.6% | 4 | 0 | 2000 | 92.7% |
| | 4 | 99.6% | 4 | 0.06 | 2000 | 89.9% |
| | 4 | 99.6% | 4 | 0.12 | 2000 | 81.8% |
| Case 1 of | 4 | 99.6% | 4 | 0.12 | 2000 | 90.9% |
| the | | | | | | |
| application | | | | | | |
| Case 2 of | 4 | 99.6% | 4 | 0.12 | 2000 | 92.3% |
| the | | | | | | |
| application | | | | | | |
| Case 3 of | 4 | 99.6% | 4 | 0.12 | 2000 | 92.5% |
| the | | | | | | |
| application | | | | | | |
| Prior art | 4 | 99.6% | 3 | 0 | 2000 | 88.5% |
| | 4 | 99.6% | 3 | 0.06 | 2000 | 83.9% |
| | 4 | 99.6% | 3 | 0.12 | 2000 | 73.8% |
| Case 1 of | 4 | 99.6% | 3 | 0.12 | 2000 | 85.4% |
| the | | | | | | |
| application | | | | | | |
| Case 2 of | 4 | 99.6% | 3 | 0.12 | 2000 | 86.5% |
| the | | | | | | |
| application | | | | | | |
| Case 3 of | 4 | 99.6% | 3 | 0.12 | 2000 | 87.1% |
| the | | | | | | |
| application | | | | | | |

From Table 1, it can be observed that as the standard deviation increases, the recall rate of the present embodiment improves significantly compared to the prior art. For instance, when the standard deviation is 0.12, the present embodiment can improve the recall rate from 81.8% to 92.5%.

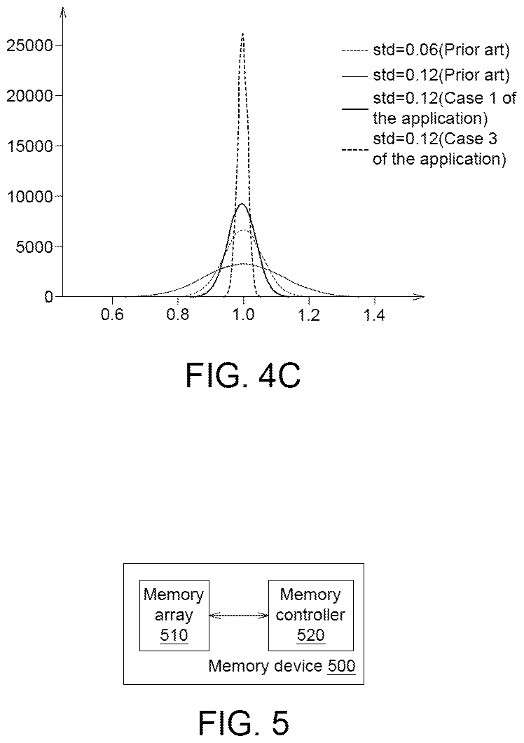

FIG. 5 illustrates a functional block diagram of a memory device according to an embodiment of the present disclosure. As shown in FIG. 5, the memory device 500 according to one embodiment includes a memory array 510 and a memory controller 520. The memory array 510 is coupled to the memory controller 520. When reading from or performing in memory computing on the memory array 510, the memory controller 520 controls the memory array 510 to implement the content of the embodiments described above, with details omitted here.

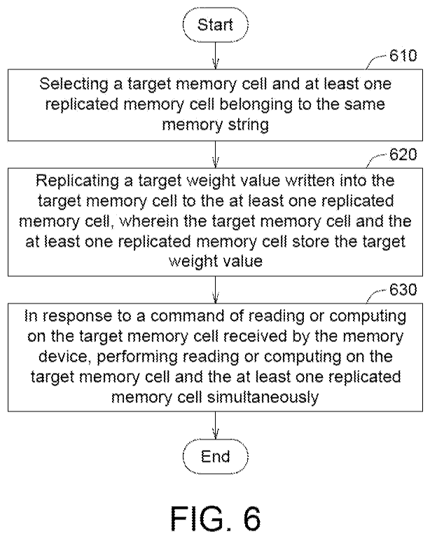

FIG. 6 shows an operation method flowchart of the memory device according to an embodiment of the present disclosure. The method of operating the memory device comprises: (610) selecting a target memory cell and at least one replicated memory cell belonging to the same memory string; (620) replicating a target weight value written into the target memory cell to the at least one replicated memory cell, wherein the target memory cell and the at least one replicated memory cell store the target weight value; and (630) in response to a command of reading or computing on the target memory cell received by the memory device, performing reading or computing on the target memory cell and the at least one replicated memory cell simultaneously.

The above embodiments of the present disclosure involve a memory device designed to reduce computational noise in memory and improve computational efficiency.

In the present embodiments, by activating (or reading mode) multiple memory cells (programmed with the same weight values or the same stored data) in a memory string, robustness of the system is enhanced. In other words, the present embodiments can enhance the reliability of the system by activating multiple memory cells in a memory string or operating in reading mode.

The present embodiments can be applied to various memory technologies, including 2D/3D NAND flash memory, 2D/3D phase-change memory (PCM), 2D/3D resistive random-access memory (RRAM), 2D/3D magnetoresistive random-access memory (MRAM), and other different memory architectures. The present embodiments are not limited to specific types of memory but can be applied to various memory architectures.

The present embodiments can be applied not only to non-volatile memory but also to volatile memory. In other words, the present embodiments are flexible and universal.

When applied to in-memory computation (IMC), the present embodiments have the potential to reduce memory variability and improve the robustness of the system. Specifically, when the present embodiments are applied to in-memory computation (IMC), the present embodiments help reduce the variability of memory operations while enhancing system reliability.

In summary, the present embodiments provide superior performance and reliability in in-memory computation (IMC). The present embodiments can enhance the performance in environments such as VVM (vector-vector matrix), MAC, HDC (high dimension computing), improving the overall efficiency of the system.

The applications of the present embodiments are broad, including in computational processing, especially in memory involving VVM/MAC/HDC and standard read mode.

The present embodiments can play a role in General Matrix Multiplication (GEMM). GEMM is a fundamental linear algebra operation typically used for linear operations on large datasets. The present embodiments may be applied in performing GEMM operations in memory, thereby improving the efficiency and accuracy of matrix multiplication.

The present embodiments can provide optimization under standard memory read operations, as they can improve the speed and reliability of reading data from memory, enhancing the overall performance of the system.

The present embodiments can also be applied to Hyper-dimensional Computing (HDC). In HDC, the system needs to handle more complex and massive datasets. The present embodiments can play a role in handling complex computing tasks.

Additionally, the present embodiments can be applied to Hamming Distance Computing: This technology can also be applied. Hamming Distance is used to measure the number of differing bits between two equally long strings. The present embodiments may play a role in applications requiring bit-level comparisons and computing similarity, such as data matching, pattern recognition, and more.

In conclusion, the present embodiments is flexible and has the potential to enhance the computational performance, robustness, and ability to handle complex data in various computing scenarios.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A method of operating a memory device, comprising:
selecting a target memory cell and at least one replicated memory cell belonging to the same memory string;
replicating a target weight value written into the target memory cell to the at least one replicated memory cell, wherein the target memory cell and the at least one replicated memory cell store the target weight value; and
in response to a command of reading or computing on the target memory cell received by the memory device, performing reading or computing on the target memory cell and the at least one replicated memory cell simultaneously.

2. The method of operating the memory device according to claim 1, wherein the target memory cell and the at least one replicated memory cell are serially connected within the memory string.

3. The method of operating the memory device according to claim 1, wherein
the target memory cell is coupled to a target word line;
the at least one replicated memory cell is coupled to at least one replicated word line, and
in reading the target memory cell, both the target word line and the at least one replicated word line are simultaneously selected to simultaneously activate the target memory cell and the at least one replicated memory cell.

4. The method of operating the memory device according to claim 3, wherein in performing computing on the target memory cell, the target word line and the at least one replicated word line receive the same input value.

5. The method of operating the memory device according to claim 1, wherein
the memory device is a 2D/3D NAND flash memory, a 2D/3D phase-change memory (PCM), a 2D/3D resistive random-access memory (RRAM), or a 2D/3D magnetoresistive random-access memory (MRAM); and
the memory device is a non-volatile memory or a volatile memory.

6. A memory device comprising:
a memory array; and
a memory controller coupled to the memory array,
wherein the memory controller is configured to:
selecting a target memory cell and at least one replicated memory cell belonging to the same memory string;
replicating a target weight value written into the target memory cell to the at least one replicated memory cell, wherein the target memory cell and the at least one replicated memory cell store the target weight value; and
in response to a command of reading or computing on the target memory cell received by the memory device, performing reading or computing on the target memory cell and the at least one replicated memory cell simultaneously.

7. The memory device according to claim 6, wherein the target memory cell and the at least one replicated memory cell are serially connected within the memory string.

8. The memory device according to claim 6, wherein
the target memory cell is coupled to a target word line;
the at least one replicated memory cell is coupled to at least one replicated word line, and
in reading the target memory cell, both the target word line and the at least one replicated word line are simultaneously selected to simultaneously activate the target memory cell and the at least one replicated memory cell.

9. The memory device according to claim 8, wherein in performing computing on the target memory cell, the target word line and the at least one replicated word line receive the same input value.

10. The memory device according to claim 6, wherein
the memory device is a 2D/3D NAND flash memory, a 2D/3D 5 phase-change memory (PCM), a 2D/3D resistive random-access memory (RRAM), or a 2D/3D magnetoresistive random-access memory (MRAM); and
the memory device is a non-volatile memory or a volatile memory.
